(19) United States
(12) Patent Application Publication
(10) Pub. No.: US 2008/0150596 A1
(43) Pub. Date: Jun. 26, 2008

(54) CHARGE PUMP CIRCUIT

(76) Inventors: Eyal Fayneh, Giyatyim (IL); Ernest Knoll, Haifa (IL)

Correspondence Address: INTEL/BLAKELY, 1279 OAKMEAD PARKWAY, SUNNYVALE, CA, 94085-4040, US

(21) Appl. No.: 11/615,753

(22) Filed: Dec. 22, 2006

(51) Int. Cl. H03L 7/06

(52) U.S. Cl. 327/157

(57) ABSTRACT

Disclosed herein are embodiments of a charge pump that can provide an output voltage with an output current that remains sufficiently constant over an operating range of the output voltage

### BRIEF DESCRIPTION OF THE DRAWINGS

Embodiments of the invention are illustrated by way of example, and not by way of imitation, in the figures of the accompanying drawings in which like reference numerals refer to similar elements.

FIG. 1 is a diagram of a conventional self biased phase locked loop (PLL) circuit.

FIG. 2 is a diagram of a high performance charge pump circuit for use with the self biased PLL of FIG. 1.

FIG. 3 is a diagram of a phase locked loop (PLL) circuit in accordance with some embodiments.

FIG. 4 is a schematic diagram of a charge pump circuit for use with the PLL of FIG. 3 in accordance with some embodiments.

FIG. 5 is a block diagram of a computer system having a processor with at least one PLL in accordance with some embodiments of the invention.

### DETAILED DESCRIPTION

The present invention pertains to charge pump circuits, e.g., for a phase locked loop (PLL) or delay locked loop (DLL) circuit. In particular, it relates to a charge pump that can provide a charge pump current (I_{CP}) versus control voltage (Vcntl) response that can be suitably flat to attain a desired performance. For non-self biased PLL's, keeping the charge pump current relatively constant with control voltage (Vcntl) can allow the PLL to meet criteria for stable operation over a frequency range and at the same time, can enable desired results such as improved phase-jitter performance and faster PLL lock time. Before discussing embodiments of the invention, however, a conventional self-biased PLL with a charge pump, having a downwardly sloping output current response, will be discussed for better understanding of the novel circuitry.

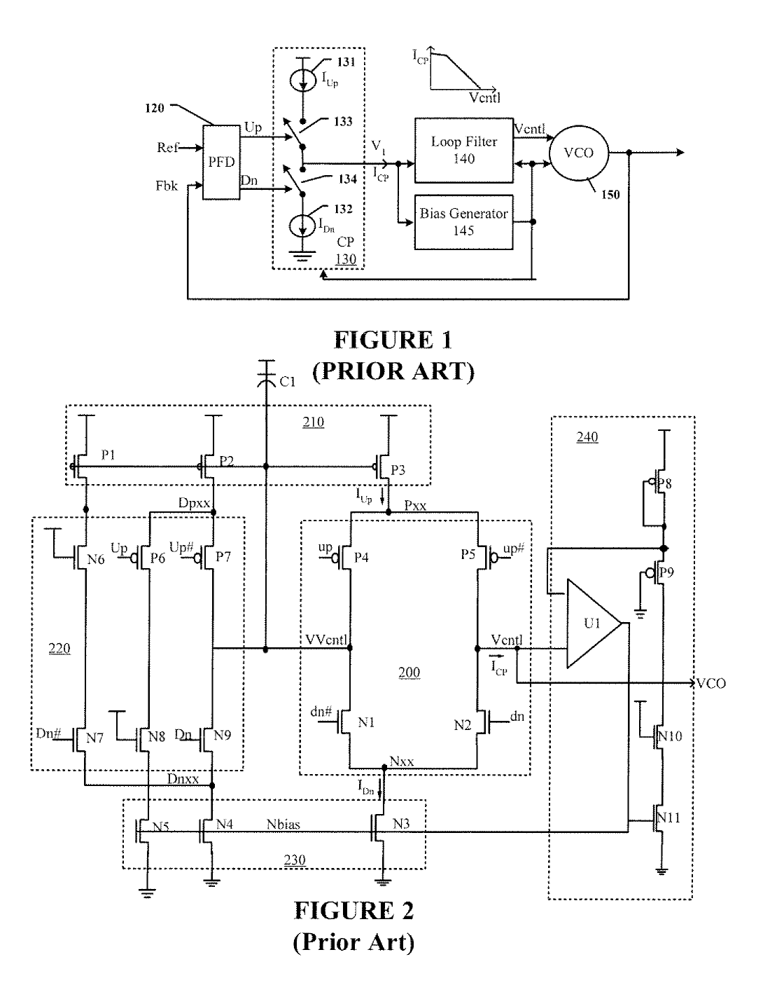

FIG. 1 is a diagram showing a conventional self-biased phase locked loop (PLL) circuit. It comprises a phase-frequency detector 120, a charge pump 130, a loop filter 140 (with an adaptive resistor element), a bias generator 145, and a voltage-controlled oscillator 150. The charge pump 130 is a self-biased charge pump, configured with the loop filter 140, bias generator 145 and VCO 150, to make the PLL self-biased. With a self-biased PLL, bias signals, common to the charge pump, loop filter, and VCO, control operating parameters such as Vcntl and I_{CP} to vary with operating frequency in order to provide for a relatively wide operational range

The phase-frequency detector compares a reference signal REF and a feedback signal FBK to determine whether a frequency and/or phase difference exists between them. The feedback signal may directly correspond to the output of the voltage-controlled oscillator or may constitute a divided version of this output, achieved, e.g., by placing a divider circuit in a feedback path connecting the VCO and phase-frequency detector.

The charge pump includes a current source 131 to source current I_{Up} to the loop filter and a current sink 132 to sink current (I_{Dn}) from the loop filter. The current source 131 may be a positive current source and the current sink 132 may be a negative current source. The symbol I_{CP} represents the current output from the charge pump. (It is noted that this figure illustrates how an ideal charge pump with I_{Up}=I_{Dn}, works. The circuits of FIGS. 2 and 4 approach this but of course are not perfect given real-world limitations.)

In operation, the phase-frequency detector determines whether a phase (or frequency) difference exists between the reference and feedback signals. If a difference exists, the detector outputs one of an Up signal and a Down signal to control the output of the charge pump. If the phase of the reference signal leads the phase of the feedback signal, the Up signal may be asserted. In this case, switch 133 will close and the current signal output from the charge pump will correspond to the output of current source 131, e.g., I_{CP}=I_{Up}. Conversely, if the phase of the reference signal lags the phase of the feedback signal, switch 134 will close and the Down signal may be asserted. In this case, the current signal output from the charge pump will correspond to the output of current source 132, e.g., I_{CP}=I_{Dn}. Which signal is asserted depends on the phase/frequency relationship between the reference and feedback signals,

The amount of time current is sourced to or sinked from the loop filter corresponds to the width of the pulse of I_{CP}. Since the width of this pulse is proportional to the phase/frequency difference between the reference and feedback signals, the loop filter will charge/discharge for an amount of time that will bring the phases of these signals into coincidence. The resulting signal output from the loop filter will therefore control the VCO to output a signal at a frequency and a phase which is not substantially different from the reference signal input into the phase-frequency detector.

The charge pump may operate in one of four modes: CHARGE mode, PUMP mode, OVERLAP mode, and OFF mode. In CHARGE mode, a rising edge of the reference signal REF appears at the input of the phase-frequency detector. At this time, the detector outputs a switching voltage signal Up to the charge pump. This signal closes the Up switch to cause the charge pump to output charge current I_{Up} such that I_{CP}=I_{Up}. In this mode, the charge pump therefore drives current into the loop filter of the PLL. On the other hand, in PUMP mode, a rising edge of the feedback signal FBK signal appears at the input of the phase-frequency detector. At this time, the detector outputs a switching voltage signal Dn to the charge pump. This signal closes the Dn switch to cause the charge pump to sink current from the loop filter of the phase locked loop equal to I_{Dn}.

In OVERLAP mode, the rising edge of the reference signal is input into the phase-frequency detector essentially at the same time the charge pump is operating in pump mode (i.e., the Dn switch is closed). Because both the Up switch and Dn switch are closed at this time, I_{Up} current from the charge current source flows into the down current sink. As a result, no current should flow out of or into the charge pump during this mode. (Note that this is a characteristic of an idealized charge pump that can be difficult to achieve in practice thereby leading to errors resulting from current leaking into or leaching out of the loop filter during the OVERLAP mode.) OVERLAP mode may also occur if the charge pump is operating in charge mode at the same time the rising edge of the feedback signal is input into the phase-frequency detector. This will cause the phase-frequency detector to assert the Dn switching signal and thus close the Dn switch. In either case, the charge pump current I_{CP} should assume a value of zero.

In OFF mode, the Up and Dn switches are both opened. As a result, the current sources of the charge pump are decoupled from the loop filter and no current should flow into or out of the loop filter.

The operation of the phase-locked loop may therefore be summarized as follows. When the phase-frequency detector detects a phase difference between the reference and feedback signals, the charge pump outputs a current pulse having a width (duration) corresponding to the phase difference. The current pulse determines a voltage variation at the loop filter output. This variation is proportional to the current pulse width and thus determines a VCO steering line voltage change which produces a VCO frequency shift that corrects the phase difference.

Under ideal conditions, when the phase difference between the reference and feedback signals is zero, the current pulse width and average charge pump output current are zero and no correction occurs in the loop. However, under non-ideal (or practical) conditions, the average current output from the charge pump is zeroed for a non-zero phase difference. The non-zero phase difference, which exists under this condition, is referred to as steady state DC skew of the phase-locked loop (PLL). The circuit of FIG. 2 addresses this problem by providing a charge pump with circuitry to substantially maintain I_{Up} equal to I_{Dn} to inhibit current from leaking into or out from the loop filter during an overlap mode.

As represented in the graph next to the charge pump block, the charge pump output current (I_{CP}) changes inversely with the control voltage (Vcntl). At the same time, a resistor in the loop filter (whose product with the charge pump current makes up a loop gain factor) increases with the control voltage. This results in the gain factor staying substantially constant even as the frequency changes providing for stable operation over the operating frequency range of the PLL, which allows for a relatively wide operating range.

FIG. 2 shows a more detailed embodiment of a charge pump circuit 130. It includes an output section 200, a source section 210, a dummy section 220, a sink section 230, and a bias generator section 240.

The output section includes a symmetrical arrangement of four transistors P4, P5, N1, and N2. The transistors are coupled to respectively form Up (source) and Down (sink) switch circuits of the charge pump.

(Note that the term “P transistor” refers to a P-type metal oxide semiconductor field effect transistor. Likewise, “N transistor” refers to an N-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs and oxide thicknesses to mention just a few. Moreover, unless specifically referred to as MOS or the like, the term transistor can include other suitable transistor types, e.g., junction-field-effect transistors, bipolar-junction transistors, and various types of three dimensional transistors, known today or not yet developed.

The source section 210 comprises transistors P1, P2,and P3, with P3 serving as a source transistor for the output node Vcntl. Similarly, the sink section 130 comprises transistors N3, N4, and N5, with N5 serving as a sink transistor for the output node Vcntl.

The dummy section 220 includes a first pair of coupled transistors N6 and N9, a second pair of coupled transistors P6 and N8, and a third pair of coupled transistors P7 and N9. The gates of transistors N6 and N8 are coupled to a voltage source and therefore these transistors are switched on. The gates of transistors N7, P6, P7, and N9 are respectively switched by signals Dn#, Up, Up#, and Dn outputs from the phase-frequency detector of the PLL. Preferably, the signals are buffered in a CMOS buffer prior to input into the dummy stage to provide equal slew rates.

Capacitor C1 is coupled between VVcntl and VCC. VVcntl (or virtual Vcntl) is a virtual (or mirrored) version of Vcntl. VVcntl is also coupled to the gates of the 3 P transistors of the source section 210 (namely transistors P1, P2, and P3). The capacitor is preferably included to stabilize VVcntl while the Up/Up# and Dn/Dn# signals are toggling.

The transistors in the output section are switched by the Up/Up# and Dn/Dn# signals from the phase-frequency detector to generate the output control voltage Vcntl, which corrects the frequency of a VCO to reduce or eliminate a phase difference between reference and feedback signals of a PLL. The Up and Dn signals, and their complements, may be buffered in a CMOS buffer prior to input into the dummy stage, and the amplitudes of switching signals Up, Up#, Dn, and Dn# may correspond to a circuit supply voltage VCC.

The bias generator section 240 comprises buffer amplifier U1, P transistors P8, P9, and N transistors N10, and N11 coupled together as shown. The transistors form a stack to model corresponding transistors from the source, dummy and sink sections to control the source and sink section transistor bias levels. They are controlled so that the Up current (I_{Up}) remains equal to the Dn current (I_{Dn}) over changes in process, voltage, and temperature and over the operating range of the output control voltage.

A positive voltage change at the Nbias node leads to a negative voltage change at the Vcntl node. The Up current is controlled by VVcntl, which is a replica of Vcntl. Thus, the Up current is indirectly controlled by Nbias, while Dn current is directly controlled by the Nbias voltage.

Operation of the output stage of the charge pump will now be described for each mode of operation of the charge pump. In CHARGE mode, Up is high, Dn is low, Up# is low, and Dn# is high. These signals cause transistors P5 and N1 to be switched on and transistors P4 and N2 to be switched off. As a result, current from source transistor P3 flows through node Pxx and transistor PS to the Vcntl output, and current from current source P2 flows through switch P7 of the dummy section and then through transistor N1 to node Nxx and current source N3. Dummy current from current source P1 flows through transistors N6 and N1 and node Dnxx to sink transistor N4.

In PUMP mode, Up is low, Dn is high, Up# is high, and Dn# is low. These signals cause transistors P4 and N2 to be switched on and transistors P5 and N1 to be switched off As a result, transistor N2 causes current to be sinked from Vcntl through node Nxx to the sink transistor N3. Transistor P4 draws current from current source P3 through transistor N9 of the dummy stage through node Dnxx to sink transistor N4. Dummy current from current source P2 flows through node Dpxx and transistors P6 and N8 to sink transistor N5.

In OVERLAP mode, Up is high, Dn is high Up# is low, and Dn# is low. These signals cause transistors PS and N2 to be switched on and transistors P4 and N1 to be switched off As a result, current flows from current source P3 through node Pxx, transistors P5 and N2, node Nxx through sink transistor N3. No current goes to the Vcntl output and no current flows from the dummy section to the output section. Dummy current from current source P2 flows through node Dpxx, transistors P7 and No and node Dnxx to sink transistor N4.

In OFF mode, Up and Dn are low and Up# and Dn# are high. These signals cause transistors P4 and N1 to be switched on and transistors PS and N2 to be switched off. As a result, current from source P3 flows through node Pxx, transistors P4 and N1, and node Nxx to sink transistor N3. No current flows from the dummy stage to the output stage. Dummy current from current source P2 flows through node Dpxx and transistors P6 and N8 to sink transistor N5, while dummy current from current source P1 flows through transistors N6 and N7 through sink transistor N4.

The circuits of FIGS. 1 and 2 work well except that they may have some drawbacks depending on desired performance objectives. For example, they can have undesired phase jitter degradation, especially at lower frequencies of their operating range. Accordingly, novel embodiments improving on these designs are presented in the following sections.

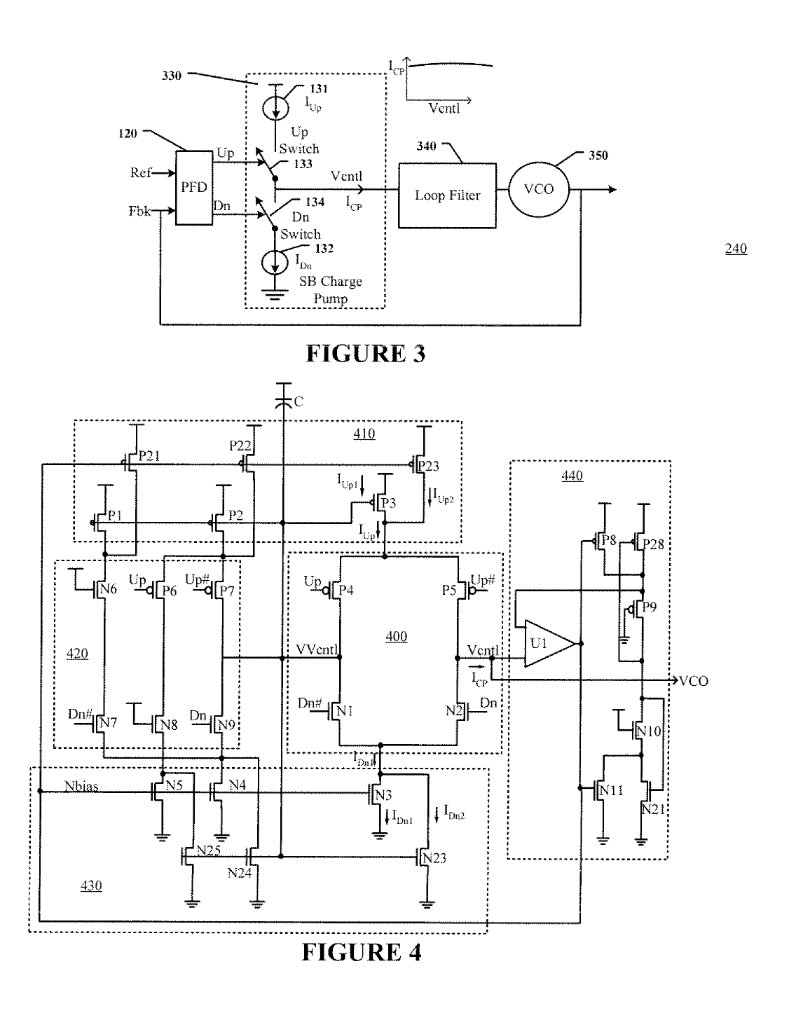

FIG. 3 is a diagram of a non-self biased PLL circuit in accordance with some embodiments. It comprises a phase-frequency detector, as discussed above, but has a charge pump 330 with a substantially constant current response. This may be desirable in many non self-biased PLL circuits where the VCO 350 is not self-biased (e.g., substantially constant gain over frequency/Vcntl) and the loop filter 340 (or equivalent) has a substantially constant gain resistor. With the charge pump's constant output current (I_{CP}), the damping factor effectively stays the same resulting in stable operation over the frequency range of the PLL. At the same time, the PLL can “lock” more quickly because the charge pump 330 does not have a “zero” (or very small) current operating point, so the control voltage (Vcntl) can be at any point in its operating range during start-up and have sufficient current for more quickly locking the PLL.

FIG. 4 shows an example of a charge pump circuit with a flat current response suitable for use in the PLL of FIG. 3. It generally comprises an output section 400, a source section 410, a dummy section 420, a sink section 430, and a bias generator section 440 coupled together as shown. It's similar to the charge pump circuit of FIG. 2 in that the bias generator circuit 440 controls the source and sink sections to maintain the Up and Dn currents equal to one another. In addition, however, circuitry is included so that the source and sink, sections include transistors controlled by the Nbias signal and the VVcntl signal so that the output current (I_{CP}) remains substantially constant over the Vcntl operating range. (Note that substantially constant means that it remains reasonably consistent, e.g., no more than a 10% deviation, over its operating Vcntl range.) Transistors from the circuit of FIG. 4 are numbered the same as in FIG. 2 and operate the same way.

The current source supplying current to the output node, Vcntl, is implemented with two P devices, P3 and P23. P3 is controlled by VVcntl, while P23 is controlled by the Nbias voltage. Similarly, the current sink sinking current from the Vcntl node is implemented with two N sink transistors, N3 and N23. N3 is controlled by the Nbias voltage, while N23 is controlled by VVcntl. Thus, the Dn current sink transistors and the Up current source transistors are controlled simultaneously by both nbias voltage and VVcntl bias voltage.

The Up current (I_{Up}) is the sum of the currents of P3 and P23 (I_{Up1}+I_{Up2}). When the Nbias voltage increases, I_{Up2} decrease. At the same time, the increase in the Nbias voltage causes Vcntl and VVcntl to decrease. This voltage decrease causes Iᵤₚ₁ to increase. The total current I_{Up}, which is equal to the sum of I_{Up1} and I_{Up2} is thereby maintained constant.

Similarly, the Dn current (I_{Dn}) is the sum of the drain currents of N3 and N23. When the Nbias voltage increases, I_{Dn1} increases. At the same time, the increase in the Nbias voltage causes Vcntl and VVcntl to decrease. This voltage decrease causes I_{Dn2} to decrease. The total current I_{Dn}, which is equal to the sum Of I_{Dn1} and I_{Dn2}, is accordingly maintained constant,

With this configuration, not only does I_{Up} stay substantially equal to I_{DN} over the various modes of operation, but also, I_{Up} and I_{DN} remain effectively the same in magnitude thereby resulting in a substantially constant I_{CP}. For example, in some embodiments of the circuit of FIG. 4 with Vcntl operating between 0.2V to 0.8V, the charge pump output current changes less than 3%, which is effectively constant charge pump current versus Vcntl.

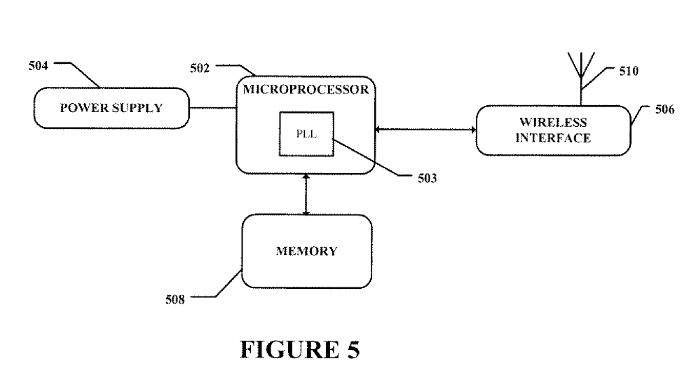

With reference to FIG. 5, one example of a computer system is shown. The depicted system generally comprises a processor 502 that is coupled to a power supply 504, a wireless interface 506, and memory 508. It is coupled to the power supply 504 to receive from it power when in operation. The wireless interface 506 is coupled to an antenna 510 to communicatively link the processor through the wireless interface chip 506 to a wireless network (not shown). Microprocessor 502 comprises one or more non self-biased PLL circuits 503 such as the circuit of FIG. 3. For example, a PLL 503 may be implemented to link the processor with the memory 508 and/or wireless interface 506.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion., and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A charge pump circuit, comprising:
a current source to provide current to an output node in response to a first control signal, the output node providing an output voltage; and
a current sink to sink current from the output node in response to a second control signal, wherein current supplied at the output node remains substantially constant over an operational range of the output voltage.

2. The charge pump of claim 1, in which the supplied output current deviates no more than 10% over the operational output voltage range.

3. The charge pump of claim 1, comprising a bias generator circuit to generate a bias signal coupled to both the current source and sink.

4. The charge pump of claim 3, in which the current source comprises first and second source transistors coupled to provide current to the output node, the first source transistor being controllably coupled to the bias signal and the second source transistor being controllably coupled to the output voltage.

5. The charge pump of claim 4, in which the second source transistor is controllably coupled to a mirror voltage of the output voltage.

6. The charge pump of claim 4, in which the current sink comprises first and second sink transistors coupled to sink current from the output node, the first sink transistor being controllably coupled to the bias signal and the second sink transistor being controllably coupled to the output voltage.

7. The charge pump of claim 4, in which the second sink transistor is controllably coupled to a mirror voltage of the output voltage,

8. A non self-biased PLL comprising the charge pump of claim 1, a loop filter, and a VCO operably coupled to the output node of the charge pump to generate an output frequency in response to the charge pump output voltage.

9. A charge pump circuit, comprising:
an output section having an- output node to provide an output control voltage and an output charge pump current;
a source section having at least one source transistor coupled to the output section to provide the output node with current during a charge mode;
a sink section having at least one sink transistor coupled to the output section to sink current from the output node during a pump mode;
a dummy section having at least one transistor coupled between the source and sink sections to transfer current between the source, output, and sink sections; and
a bias generator circuit to generate a bias signal coupled to the at least one source and sink transistors to maintain the current from the at least one source transistor substantially the same as the current going into the at least one sink transistor and to maintain substantially constant the output charge pump current over an operating range of the output control voltage in the charge and pump modes.

10. The charge pump of cl aim 9, in which the output charge pump current deviates no more than 5% over the operating output control voltage range.

11. The charge pump of claim 9, in which the at least one source transistor comprises a first source transistor coupled to the bias signal and a second source transistor coupled to the output control voltage.

12. The charge pump of claim 11, in which the second source transistor is coupled to the output control voltage through a virtual output control voltage node.

13. The charge pump of claim 10, in which the at least one sink transistor comprises a first sink transistor coupled to the bias signal and a second sink transistor coupled to the output control voltage.

14. The charge pump of claim 11, in which the second sink transistor is coupled to the output control voltage through a virtual output control voltage node.

15. The charge pump of claim 13, in which the bias generator comprises transistors modeling the first and second source transistors and transistors modeling the first and second sink transistors.

16. A PLL circuit comprising a charge pump circuit in accordance with the charge pump circuit of claim 9.

17. A computer system, comprising:
a processor chip having at least one PLL with a charge pump circuit comprising a current source to provide current to an output node in response to a first control signal, the output node providing an output voltage, and a current sink to sink current from the output node in response to a second control signal, wherein current supplied at the output node remains substantially constant over an operational range of the output voltage;
a memory chip coupled to the processor chip to provide it with additional random access memory; and
an antenna coupled to the processor chip to communicatively link it to a wireless network.

18. The computer system of claim 17, in which the output current supplied from the charge pump deviates no more than 10% over the operational output voltage range.

19. The computer system of claim 17, in which the charge pump comprises a bias generator circuit to generate a bias signal coupled to both the current source and sink.

20. The charge pump of claim 19, in which the current source comprises first and second source transistors coupled to provide current to the output node, the first source transistor being controllably coupled to the bias signal and the second source transistor being controllably coupled to the output voltage.
